(19) United States
(12) Patent Application Publication
(10) Pub. No.: US 2008/0149170 A1
(43) Pub. Date: Jun. 26, 2008

(54) Plug-Together Photovoltaic Modules

(75) Inventor: Jack I. Hanoka, Brookline, MA (US)

Correspondence Address: BROMBERG & SUNSTEIN LLP, 125 SUMMER STREET, BOSTON, MA, 02110-1618, US

(73) Assignee: EVERGREEN SOLAR, INC., Marlborough, MA (US)

(21) Appl. No.: 11/956,785

(22) Filed: Dec. 14, 2007

Related U.S. Application Data
(60) Provisional application No. 60/875,174, filed on Dec. 15, 2006.

(51) Int. Cl. H01L 31/05; H01R 24/00

(52) U.S. Cl. 136/251; 439/625

(57) ABSTRACT

A solar cell module adapted for direct intercoupling with another solar cell module. The solar cell module has a plurality of photovoltaic cells disposed within an integral enclosure, a plurality of bypass diodes coupled in shunt across a subset of the plurality of photovoltaic cells, and at least one electrical connector adapted for intercoupling with another solar cell module constituting the sole path for delivery of electrical power from all of the plurality of photovoltaic cells of the solar cell module. Stiffening members may be coupled to a backskin of the solar cell module for providing rigidity of the module with respect to deflection.

The present application claims priority from U.S. Provisional Patent Application Ser. No. 60/875,174, filed Dec. 15, 2006, which is incorporated herein by reference.

### TECHNICAL FIELD

The present invention relates to photovoltaic (PV) modules, and, more particularly, to methods for forming PV modules that are stiffened and that permit direct coupling of adjacent modules. By virtue of such direct coupling, the need for junction boxes and wires with plugs on the end of these wires may be advantageously eliminated, thereby simplifying, and lowering the cost of, both manufacturing and installing photovoltaic modules.

### BACKGROUND ART

Photovoltaic modules, particularly those made with crystalline silicon solar cells, are typically produced by providing a sheet of tempered glass, depositing a transparent encapsulant on the glass, positioning solar cells on the encapsulant, depositing a second encapsulant layer on the cells, positioning a backsheet layer on top of the second encapsulant layer, securing a perimeter aluminum frame, and bonding a junction box to the backsheet on the rear of the modules. Common practice is to have wires with plugs emerging from this junction box. Furthermore, bypass diodes can be incorporated in the junction box to provide for protection in case of cell shading in the module. Prior to the installation of the aluminum frame, a strip of some type of gasketing material may be applied to the edge of the glass as a cushioning layer to protect the edge of the tempered glass from shattering due to an edge impact.

### SUMMARY OF THE INVENTION

In accordance with preferred embodiments of the present invention, solar cell modules are provided with features that allow them to be plugged into each other without any intervening wires and that obviate the use of junction boxes. Diodes that are usually incorporated into the junction box can now be wired directly within the module. In this way, a significant cost savings in module manufacturing and installation can be achieved. This can be achieved using a unique connector design on each module and suitable polymers that surround these connectors. To form such modules, injection molding methods for polymers and elastomers may be employed in the manufacture of such modules. The polymer used can be molded and may advantageously form a weather-tight and/or weatherable seal. The polymer can be a low cost material.

In a first aspect of the invention, there is provided a solar cell module; an edge piece sealing at least one edge of the solar cell module; and a connector. The connector includes an elastomer housing formed as a portion of the edge piece and a conductor disposed in the elastomer housing

In other aspects of the invention, methods are provided for forming an electrical connection between solar cell modules. A first solar cell module is provided including a first elastomer housing formed in an edge piece of the first solar cell module. A first conductor is disposed in the first elastomer housing and is in electrical communication with at least one solar cell of the first solar cell module. A second solar cell module is provided including a second elastomer housing formed in an edge piece of the second solar cell module. A second conductor is disposed in the second elastomer housing and is in electrical communication with at least one solar cell of the second solar cell module. The first conductor of the first solar cell module and the second conductor of the second solar cell module are engaged to form the electrical connection enclosed by the first elastomer housing and the second elastomer housing.

In another aspect, the technology features a method of forming a solar cell module. An edge piece includes an elastomer housing. A conductor is disposed in the elastomer housing, and the edge piece is attached to an edge of the solar cell module.

In certain embodiments, the aspects above can include one or more of the following features. The conductor can include a single pin and a second solar cell module can include a second conductor adapted to receive the single pin. The edge piece can be formed from a polymer material. The edge piece can seal the edge of the solar cell module. The edge piece can be molded onto or laminated to the edge of the solar cell module.

The conductor can be electrically insulated from the edge piece. In some embodiments, the conductor is in electrical communication with at least one solar cell of the solar cell module. The first elastomer housing and the second elastomer housing can seal the electrical connection from environmental conditions.

In certain embodiments, a track frame is provided. The first solar cell module is disposed in the track frame, and the second module is disposed adjacent the second module so that the first conductor and the second conductor can be engaged. The edge piece can be co-extruded including a polymer portion for sealing the edge of the solar cell module and an elastomer portion for forming the elastomer housing.

### BRIEF DESCRIPTION OF THE DRAWINGS

The foregoing features of the invention will be more readily understood by reference to the following detailed description, taken with reference to the accompanying drawings, in which:

FIG. 1 is a schematic diagram of a generic layout of photovoltaic solar cells within a solar cell module.

FIG. 2 is a diagram of a typical actual electrical layout of a solar cell module.

FIG. 3 shows two modules, each having male and female connectors for intercoupling in accordance with embodiments of the present invention.

FIG. 4 shows two solar cell modules electrically connected together by engaging the male and female connectors.

FIG. 5 shows a design of male and female plug connectors in accordance with an embodiment of the present invention.

FIG. 6 is a cut-away illustration of connectors formed in an injection molded part that contains an elastomer that allows for a weather-tight seal in accordance with the embodiment of FIG. 5.

FIG. 7 shows photovoltaic solar cell modules configured as roof tiles and electrically connected in accordance with an embodiment of the present invention.

FIG. 8 shows molded-in guiding features on module edgings containing electrical connectors in accordance with an embodiment of the present invention.

FIG. 9 is a schematic depiction of a Schottky diode embedded within a buss bar in accordance with an embodiment of the present invention.

FIG. 10 shows three stiffeners bonded to the backskin of a photovoltaic module in accordance with an embodiment of the present invention.

### DETAILED DESCRIPTION OF SPECIFIC EMBODIMENTS

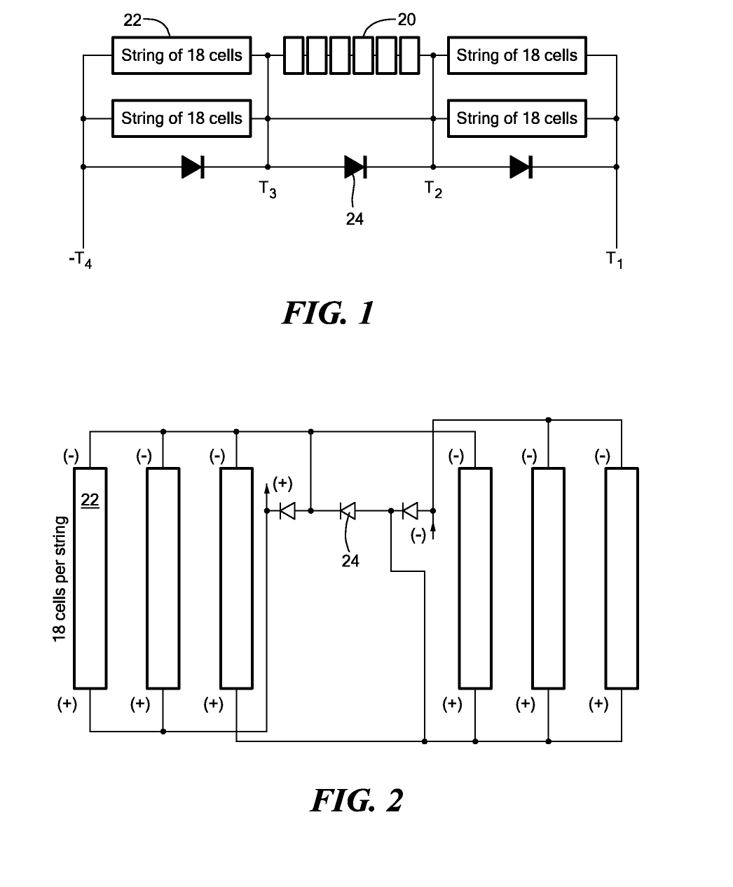

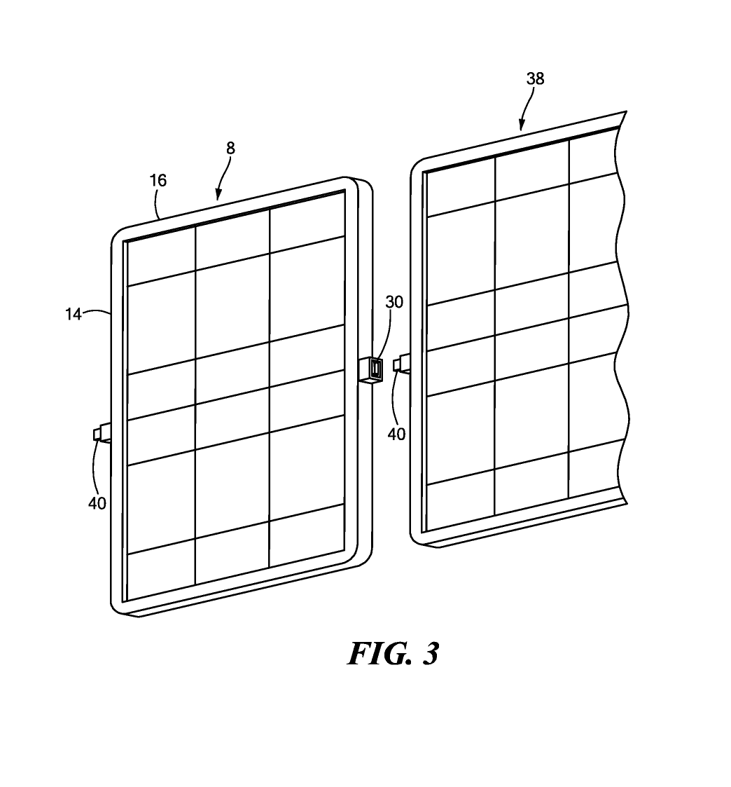

Solely for convenience of description, it will be assumed herein that a plurality of solar cells are arrayed within an integral solar cell module in a plurality of rows, each row typically comprised of multiple strings of cells. A solar cell module may be referred to herein, without limitation, as a photovoltaic (PV) module. Such a layout is shown in FIG. 1, wherein solar cells 20 are arrayed in rows. Again, solely for convenience of description, the lateral edges 14 (shown in FIG. 3) of the rows are referred to herein as “sides” of the module 8, whereas the edges of the module parallel to the rows are referred to as the “top” 16 and the “bottom” 18 of the module. It is to be understood that the teachings of the present invention are entirely general with respect to the shape of the modules and to the configuration of cells within the modules, and may be practiced whether the module edges are rectilinear or otherwise, and whether the solar cells are arranged within rows, or otherwise. Module 8 may, of course, be mounted in any configuration with respect to gravity, since its disposition in operation is governed by its orientation with respect to the sun, such that terms such as “up” and “down” are used purely for convenience of description, and with no limiting intent.

The general electrical configuration of a PV module may be described with reference to FIG. 1. Photovoltaic photocells 20 are electrically coupled in serial strings 22, in turn coupled in parallel by transverse leads 23 that may also be referred to, herein, as buss bars. Each of the parallel segments of strings 22, connected, in turn, in series, is typically shunted with a bypass diode 24, typically a Schottky diode, so that shaded areas of the PV array do not give rise to high-impedance regions in series with power-generating portions of the circuit over which power may be dissipated. Bypass diodes are connected between successive pairs of terminals T₁, T₂, T₃, and T₄, as shown, either in a junction box, or with embedded bypass diodes, as discussed below in the context of certain aspects of the present invention. A schematic of a typical physical electrical layout of the components of a PV module is shown in FIG. 2.

Electrical Connection between Adjacent PV Modules

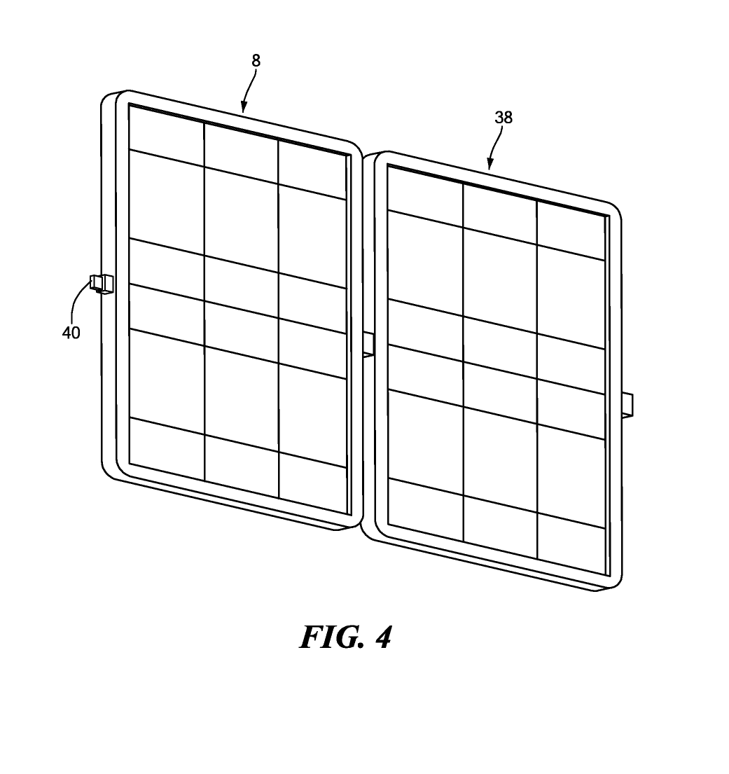

In accordance with preferred embodiments of the invention, one or more electrical connectors are employed to allow for coupling of electrical current from a first PV module to another PV module that is physically adjacent to the first module. Referring now to FIG. 3, a female connector 30 of a first module 8 can engage the male connector 32 of a second module 38. In the embodiment of the invention depicted in FIG. 3, the male and female connectors, otherwise referred to herein generically as “plugs” (with no distinction made as to “sockets”) are molded into edge pieces 14, 16, 18 that are placed on the four edges of each module prior to lamination. FIG. 4 depicts the modules 8 and 38 of FIG. 3, now electrically connected together, with male connector 40 shown, as to allow lateral coupling to a successive adjacent module (not shown).

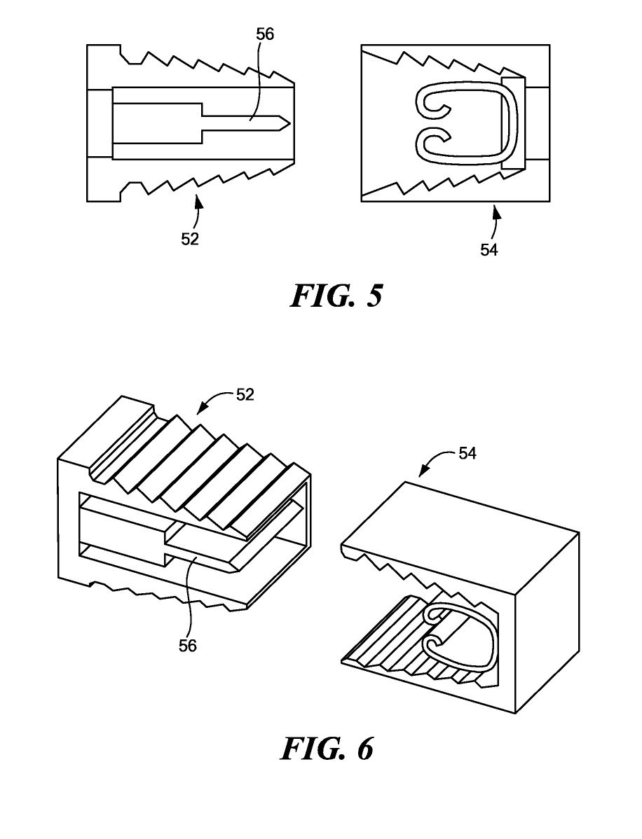

In another aspect of the technology, a connector design is utilized to allow for the direct connection of adjacent photovoltaic modules. The connector design illustrated in cross section in FIG. 5 showing the male 52 and female 54 portions of the connector concept. The male portion, which may comprise a single electrical conductor, which may, in turn, be referred to herein as a pin, has a blade shape that provides for some tolerance in the direction in which it is inserted as well as in a direction perpendicular to this direction but in the same plane as the blade shape. The female portion 54 has a bellows shape that provides for a strong spring action when the male portion engages it. An elastomeric material 56 surrounds and is bonded to the contacting parts, which can be formed from a suitable metal. The elastomeric material can have a tapered, “O-ring” design to promote sealing with respect to the ambient environment. Furthermore, such a design allows for a strong rubbing action and thus insures a good, electrical contact. One or both of the connectors can be made out of tin plated brass, tin plated phosphor bronze, or copper. The bronze has a high spring constant when formed in the typical shape shown in FIG. 5. Another embodiment uses a silver plated phosphor bronze contact. Silver can increase the resistance to fretting corrosion and consequently extend the lifetime of the contact. Perspective views of connectors 52 and 54 are shown in FIG. 6.

Edging materials for PV module 8 may be formed in a separate injection molding step, placed on the module, and electrical leads from the module joined to the connectors on the edging materials and then the entire structure may be laminated using a conventional lamination technique. In such an embodiment, the edging piece includes a connector, e.g., as shown in FIGS. 5 and 6.

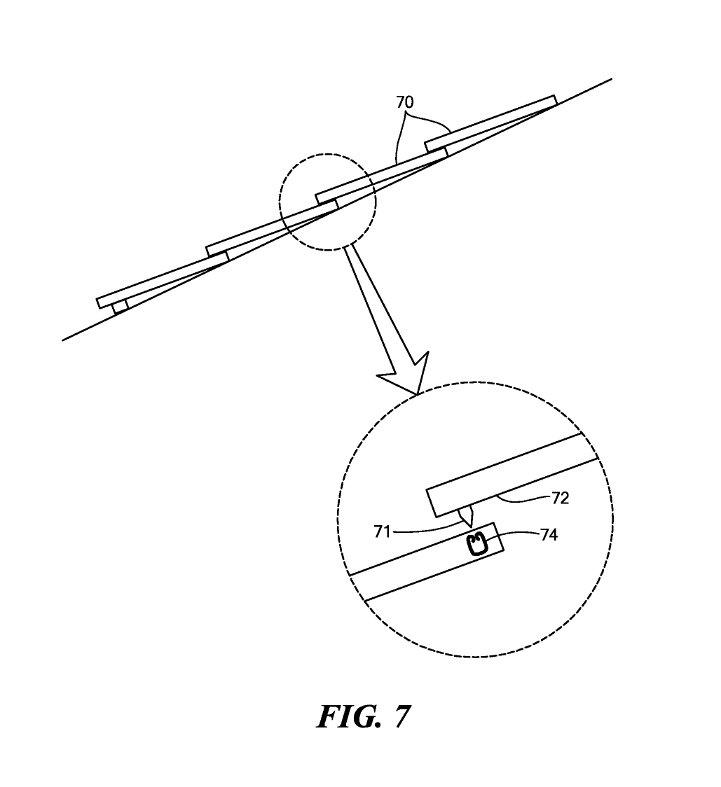

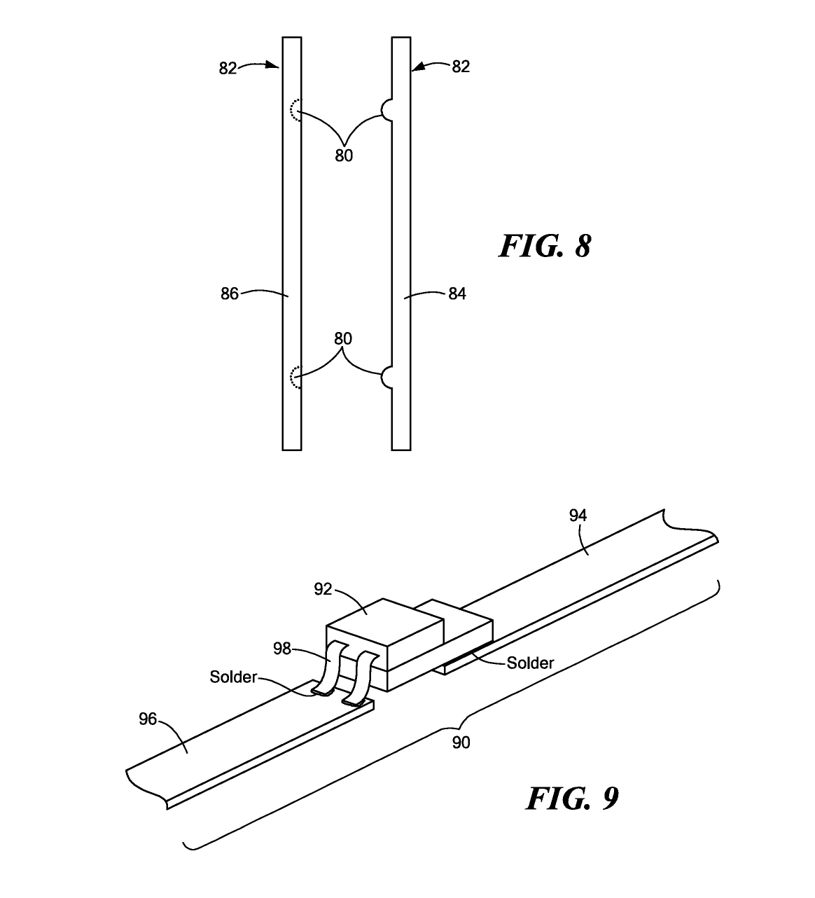

In accordance with other embodiments of the invention, the plug-together concept for coupling PV modules may also be used in a roof tile configuration of solar modules 70, as shown in FIG. 7. Exemplary methods for forming roof tiles using solar cells is described in U.S. Pat. No. 5,986,203, which is incorporated herein by reference. In such a case, the male plug element 71 may be disposed on the lower rear edge 72 of a roof tile while the female plug element 74 may be on the top front edge of the module.

A solar cell roof tile can include a front support layer, a transparent encapsulant layer, a plurality of interconnected solar cells and a backskin layer. The front support layer can be formed of light transmitting material and has first and second surfaces. The transparent encapsulant layer can be disposed adjacent the second surface of the front support layer. The interconnected solar cells can have a first surface disposed adjacent the transparent encapsulant layer. The backskin layer can have a first surface disposed adjacent a second surface of the interconnected solar cells, wherein a portion of the backskin layer wraps around and contacts the first surface of the front support layer to form the border region.

Portion of the border region can have an extended width. The solar cell roof tile can include stand-offs disposed on the extended width border region for providing vertical spacing with respect to an adjacent solar cell roof tile. A first group of stand-offs can be disposed on the border region having an extended with and a second group of stand-offs can be disposed on a second surface of the backskin layer, wherein the first group of stand-offs of a solar cell roof tile is designed to intersperse between the second group of stand-offs of an adjacent solar cell roof tile. A plug connector can be formed adjacent or between two stand-offs. In certain embodiments, a plug connector can be integrated with a stand-off.

### Methods for Forming the Plug Connecting Parts

The outer polymeric materials used to form the edging pieces of PV modules may be based on ionomers. For example, a frameless photovoltaic module can be formed using profile extruded edging pieces placed on the module assembly just prior to lamination. The polymer frame surrounding the perimeter of the module includes non-conductive edge elements, which are light weight, easy to install, and allow for improved sealing of the photovoltaic module.

When such an edging piece is formed, not by profile extrusion, but by injection molding, an elastomer can be used to form seals between the edging pieces. This elastomer can be bonded to the metal connector parts and to the outer ionomer edging material. The edges pieces can include male and female plug elements and the elastomer can be co-molded in an injection mold process. The injection molded part can be subjected to e-beam irradiation to further cross-link the outer edging material.

In another embodiment, elastomer may be injection molded with an injection molded part inserted in an edging piece formed by profile extrusion. This is followed by e-beam cross-linking of the edging piece that contains the plug assembly. The entire assembly may be laminated.

FIG. 7 shows shows edging pieces 82 that include plugs plus molded-in guiding portions to allow for aligning and then connecting one module to an adjacent one. The edging piece can be made by injection molding molded-in guiding features 80 on plug containing edgings 82. Male 84 and female 86 connectors are shown. In further embodiments, the plug-together modules can be mounted by simply sliding them along U shaped mounting channels that are mounted horizontally, either in a ground mount configuration or on a roof. The U shaped mounting channels can be a polymer or a metal and can include clips or screws that tighten onto the plug-together modules in the channels to securing them within the U channel.

### Elimination of the Junction-Box and Embedding of the Bypass Diodes

In a conventional module, a junction box (not shown) is attached to the backskin of each solar cell module. This junction box is used to hold the wires and plugs that are electrically connected to the interior of the module and to also hold the bypass diodes for the module. With the plug-together module and the elimination of the conventional wires and plugs, embedding the bypass diodes within the module can obviate any need for a junction box altogether. Embedding the bypass diodes within the module can be done as long as thermal dissipation of the diodes is properly provided for.

In accordance with various embodiments of the invention, described with reference to FIG. 9, a wider tabbing or crosstie material 94, 96 is used to connect the various strings of series connected solar cells. In the embodiment of FIG. 9, a Schottky diode 92 used for flat mounting has been soldered to two unequal lengths 94, 96 of tabbing material. The cathode side of the diode is where most of the heat is generated and so it has the longer piece 94 of tabbing material which is preferrably 4.5″×0.25″×0.014″ crosstie material. The shorter end 96 is preferably 1.5″×0.25″×0.014″ crosstie material. Such a configuration with a particular diode was tested according to the 'EC 61215 Standard (Edition 2) Bypass Diode Thermal Test and found to satisfy the requirements. This is the standard qualification test for bypass diodes in a photovoltaic module.

### Mounting Methods and Module Stiffeners

In general, a frameless, light weight photovoltaic module has improved stiffness for better resistance against deflection due to wind, ice, snow loads, or other environmentally created conditions. Conventional photovoltaic modules are made with an aluminum perimeter frame that functions to protect edges of the tempered glass used as the superstrate of the module, to provide for some level of stiffness for the module, and to allow for mounting onto amounting structure, such as a rack attached to a roof or other surface. Protective edging around the superstrate glass of the module that is low cost and simple to form can allow for a variety of mounting possibilities, can provide even greater stiffness to a module than that of an aluminum frame, and can obviate the need for grounding a module.

One or more stiffening member(s) can be applied to the rear of the module such that the need for any aluminum frame and for thicker glass can be reduced or eliminated. The stiffening members are placed at optimal locations on the rear of the module to provide for a much greater resistance to deflection under load. This means that the likelihood of cracking cells due to such deflection is greatly reduced—an important advantage as the industry shifts to thinner solar cells. Grounding wires attached to the module during installation can be eliminated because there is no exposed metal on the module and, thus the need for grounding is obviated entirely. This can be a significant cost saving for module installers who normally need to run a grounding wire connected to each module.

A frameless module can be formed by first using a backskin of a mix of polyolefins that have been irradiated. An ionomer or an acid co-polymer with about 25% high density polyethylene, along with a mineral filler, can be used.

Non-metallic materials that have sufficient strength and that can be bonded to the backskin material of a module can now be placed and bonded onto the backskin such as to optimize the placement of these stiffeners to give the module maximum stiffness. This is particularly important as PV modules become larger. Larger modules require heavier and more costly aluminum frames. Even with this, there is a limit as to how much stiffness a frame that is only on the edges of the module can provide. Just as an aluminum frame is used both as a stiffening member and also as a means of mounting the module, the non-metallic stiffeners placed on the back of the module would also serve as mounting members as well. Non-metallic stiffening members can have sufficient strength to withstand loads on the front surface of the module and similar loads against the rear surface of the module.

The classes of non-metallic materials that can be used as stiffeners and mounting members can include polymers that can contain fillers to give them additional stiffness, mechanical strength, and flame retardant properties. Examples of traditional fillers include aluminum trihydrate, calcium carbonate, calcium sulfate, carbon fibers, glass fibers, hollow glass microspheres, kaolin clay, mica, crushed silica, synthetic silica, talc, and wollastonite. A more recent development is the use of nano-clays such as montmorillinite. The latter can provide enhanced physical properties and flame retardance for very small quantities that are added to the polymer.

For low-cost materials, polymeric materials can be polyolefins such as high density polyethylene, and polypropylene. Another possibility is polyethylene terephthalate (PET). Some of the polyolefins and PET can be recycled materials instead of virgin resins and thereby even lower in cost, assuming that the properties are satisfactory in such a case.

A further class of possible materials is composites of sawdust from wood along with various polymers such as PVC and polyolefins—so called plastic lumber. These materials could also be blended with nanoparticles of clay to further enhance their physical properties.

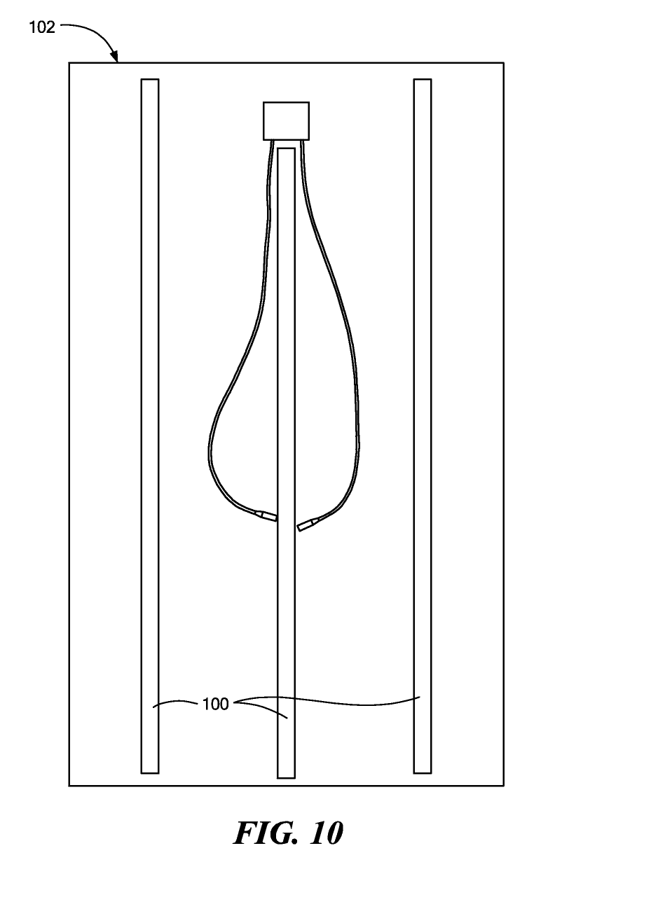

FIG. 10 illustrates the back of a full size functioning photovoltaic module, which is typically about 3′ wide and about 5′ high and has three non-metallic stiffeners 100 bonded to the backskin 102. The stiffeners are vertical, wherein “vertical” refers to a direction transverse to the arrays of PV cells, and are located in positions designed to provide maximum stiffness to the module. These stiffeners can then also be used to attach to a mounting structure, such as, for example a rack already mounted to a roof. The stiffeners, which can be bars or rods of a composite material including a polymer and a filler, can be positioned horizontally or diagonally on the backskin side of the module. It is to be understood that, within the scope of the present invention, the stiffeners may also advantageously be attached to a frame of the module in certain applications, however such attachment is not required within the scope of the invention.

The embodiments of the invention described above are intended to be merely exemplary; numerous variations and modifications will be apparent to those skilled in the art. All such variations and modifications are intended to be within the scope of the present invention as defined in any appended claims.

I claim:

1. A solar cell module adapted for direct intercoupling with another solar cell module, the solar cell module comprising:
a. a plurality of photovoltaic cells disposed within an integral enclosure;
b. a plurality of bypass diodes, each bypass coupled in shunt across a subset of the plurality of photovoltaic cells; and
c. at least one electrical connector adapted for electrical coupling of the solar cell module directly to another solar cell module, said at least one electrical connector constituting the sole path for delivery of electrical power from all of the plurality of photovoltaic cells of the solar cell module.

2. A solar cell module according to claim 1, wherein the at least one electrical connector includes two connectors of opposite polarity, one female and one male.

3. A solar cell module according to claim 2, wherein the two connectors are disposed on opposing edges of the solar cell module.

4. A solar cell module according to claim 1, wherein each electrical connector is characterized by a single conductive path.

5. A solar cell module according to claim 4, wherein the single conductive path of one electrical connector is a pin.

6. A solar cell module according to claim 1, wherein each electrical connector is co-molded with an edge component of the solar cell module.

7. A solar cell module according to claim 1, wherein the plurality of bypass diodes are enclosed within the solar cell module.

8. A solar cell module according to claim 1, wherein each of the bypass diodes is embedded in a buss bar.

9. A solar cell module according to claim 1, wherein each of the bypass diodes is a Schottky diode.

10. A solar cell module according to claim 1, wherein the at least one electrical connector includes a conductor and an elastomeric material surrounding the conductor to seal the conductor with respect to the ambient environment.

11. A solar cell module according to claim 2, wherein the two connectors are disposed on a top edge and a bottom edge, in such a manner as to allow tiling of the solar cell module with respect to adjacent solar cells disposed on a sloping surface.

12. A solar cell module according to claim 10, further comprising at least one stand-off disposed on an edge of the solar cell module in such a manner as to provide vertical spacing of the edge of the solar cell module with respect to an adjacent solar cell module.

13. An improvement to a solar cell module of the kind comprising arrays of photovoltaic diodes disposed between a transparent superstrate and a backskin, the improvement comprising at least one stiffening member coupled to the backsheet for supporting the backsheet with respect to deflection of the solar cell module.

14. The improvement of claim 12, wherein the at least one stiffening member is non-metallic.

15. The improvement of claim 12, wherein the at least one stiffening member is non-metallic.

16. A method for coupling electric current from a plurality of photovoltaic cells disposed within a solar cell module, the method comprising:
electrically coupling current from the plurality of photovoltaic cells disposed within the solar cell module directly to another solar cell module via at least one electrical connector constituting the sole path for delivery of electrical power from all of the plurality of photovoltaic cells of the solar cell module.
